(19) United States
(12) Patent Application Publication
(10) Pub. No.: US 2006/0263701 A1
(43) Pub. Date: Nov. 23, 2006

(54) Levenson phase shifting mask and method for preparing the same and method for preparing a semiconductor device using the same

(75) Inventor: Yee Kai Lai, Jungli City (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 11/181,942

(22) Filed: Jul. 15, 2005

(30) Foreign Application Priority Data
May 19, 2005 (TW) 094116262

(51) Int. Cl. G03C 5/00; G03F 1/00

(52) U.S. Cl. 430/5; 430/322; 430/323; 430/324

(57) ABSTRACT

The present method for preparing a Levenson phase shifting mask first forms a metal layer on a substrate, and an etching process is performed to form a plurality of openings in the metal layer. A spin-coating process is performed to form a polymer layer on the substrate, an electron beam is then used to irradiate on a predetermined region of the polymer layer, and the polymer layer outside the predetermined region is removed. The polymer layer may consist of hydrogen silsesquioxane (HSQ), methylsilsesquioxane (MSQ) or hybrid organic siloxane polymer (HOSP), and an alkaline solution, alcohol solution or propyl acetate can be used to remove the polymer layer outside the predetermined region. The alkaline solution is selected from the group consisting of sodium hydroxide (NaOH), potassium hydroxide (KOH) and tetramethylamomnium hydroxide (TMAH).

### BACKGROUND OF THE INVENTION

(A) Field of the Invention

The present invention relates to a Levenson phase shifting mask and method for preparing the same and method for preparing a semiconductor device using the same, and more particularly, to Levenson phase shifting mask with phase shifting patterns made of polymer material and method for preparing the same and method for preparing a semiconductor device using the same, which can eliminate the phase error problem and the intensity imbalance problem originating from the etching process.

(B) Description of the Related Art

As the integration density of semiconductor devices increases, the lithographic process needs a higher resolution to meet the precision requirement of the semiconductor device. One method to increase resolution is to use a light source with a shorter wavelength as the exposure light source, for example, the krypton fluoride (KrF) laser is used to provide the deep UV light with a wavelength 248 nanometer and the argon fluoride (ArF) laser is used to provide the deep UV light with a wavelength 193 nanometer. Another method for increasing the resolution is to use a phase shifting mask. This solution can increase lithographic resolution without changing the exposure light source, and therefore has become an important technique developed by the semiconductor industry.

FIG. 1 to FIG. 5 illustrate a method for preparing a Levenson phase shifting mask 38 according to the prior art. The prior art first deposits a chromium layer 22 on a quartz substrate 20, and the lithographic process is used to form a photoresist layer 24 including a plurality of opening patterns on the chromium layer 22. A first etching process is performed to remove a portion of the chromium layer 22 not covered by the photoresist layer 24 down to the surface of the quartz substrate 20 to form a plurality of opening patterns 26 in the chromium layer 22, and a stripping process is then performed to remove the photoresist layer 24 completely, as shown in FIG. 2.

Referring to FIG. 3, a photoresist layer 28 is formed on the quartz substrate 20 and the lithographic process is used to remove a portion of the photoresist layer 28, as shown in FIG. 4. Subsequently, a second etching process is performed to remove a portion of the quartz substrate 20 and the chromium layer 22 not covered by the photoresist layer 28 down to a predetermined depth to form an opening pattern 32 inside the quartz substrate 20, and the photoresist layer 28 is completely stripped by an oxygen plasma to expose the opening pattern 26, as shown in FIG. 5.

The difference of the propagation distance in the quartz substrate 20 between the light beam 14 penetrating the opening pattern 26 and the light beam 16 penetrating the opening pattern 32 is: Δd=d₁−d₂=mλ/└2(n_{quartz}−nₐᵢᵣ)┘, where n represents the refractive index. When a photoresist layer (not shown in the figure) is exposed by an exposure beam 12 through the phase shifting mask 38, the difference of the phase shifting angle between the light beam 14 and the light beam 16 is designed to be 180° theoretically by the depth difference between the opening pattern 26 and the opening pattern 32, which can generate a destructive interference to increase the lithographic resolution.

However, the bottom of the opening pattern 26 generated by the first etching process is difficult to position directly on the surface of the quartz substrate 20 since the first etching process cannot be controlled precisely. Similarly, the opening pattern 32 generated by the second etching process is also difficult to have a predetermined depth inside the quartz substrate 20. In addition, it is quite difficult to precisely control the profile of sidewall and the size of the opening pattern 26 and the opening pattern 32 generated by the etching process, which will generate a trapezoid opening rather than the desired rectangular opening. In other words, it is difficult to control the depth, profile and size of the opening pattern 26 and the opening pattern 32, and the phase shifting angle between the light beam 14 penetrating the opening pattern 26 and the light beam 16 penetrating the opening pattern 32 is not the theoretical value, 180°. Consequently, a phase error will occur.

In addition, a portion of the chromium layer 22 between the opening pattern 26 and the opening pattern 32 will reflect the exposure beam 12 to generate a standing wave effect, which will cause the reflected exposure beam 12 to decrease the intensity of the light beam 14 and the light beam 16. Particularly, the intensity of the light beam 16 is smaller than that of the light beam 14 due to the reflected exposure beam 12, and the intensity imbalance will occur due to inconsistent light intensity between the light beam 16 and the light beam 14 on the photoresist layer under exposure. Consequently, the developed pattern of the photoresist layer under exposure will deviate from the intended position or the developed pattern will not possess the intended line width.

### SUMMARY OF THE INVENTION

The present method for preparing a Levenson phase shifting mask first forms a metal layer on a quartz substrate, and an etching process is performed to form a plurality of openings in the metal layer. A spin-coating process is performed to form a polymer layer on the substrate, an electron beam is then used to irradiate on a predetermined region of the polymer layer, and the polymer layer outside the predetermined region is removed.

The polymer layer can include hydrogen silsesquioxane (HSQ), and a developing process using an alkaline solution is performed to remove the polymer layer outside the predetermined region, wherein the alkaline solution is selected from the group consisting of sodium hydroxide (NaOH), potassium hydroxide (KOH) and tetramethylamomnium hydroxide (TMAH). In addition, the polymer layer can include methylsilsesquioxane (MSQ), and a developing process using an alcohol solution such as an ethanol solution is performed to remove the polymer layer outside the predetermined region. Further, the polymer layer can include hybrid organic siloxane polymer (HOSP), and a developing process using a propyl acetate solution is performed to remove the polymer layer outside the predetermined region.

According to the present invention, the thickness of the quartz substrate below an opening pattern is the same as that below the phase shifting pattern. Consequently, an exposure light propagates the same distance in the quartz substrate, and the present invention can eliminate the phase error problem and the intensity imbalance problem originating from the two etching processes on the quartz substrate according to the prior art.

### BRIEF DESCRIPTION OF THE DRAWINGS

The objectives and advantages of the present invention will become apparent upon reading the following description and upon reference to the accompanying drawings in which:

FIG. 1 to FIG. 5 illustrate a method for preparing a Levenson phase shifting mask according to the prior art;

FIG. 6 to FIG. 9 illustrate a method for preparing a Levenson phase shifting mask according to one embodiment of the present invention;

FIG. 10 is a diagram showing the variation of the reflection index of the polymer layer under different wavelength according to the present invention;

FIG. 11 is a diagram showing the variation of the extinction coefficient of the polymer layer under different wavelength according to the present invention; and

FIG. 12 is a schematic diagram showing the application of the phase shifting mask to pattern a semiconductor device on a semiconductor substrate according to one embodiment of the present invention.

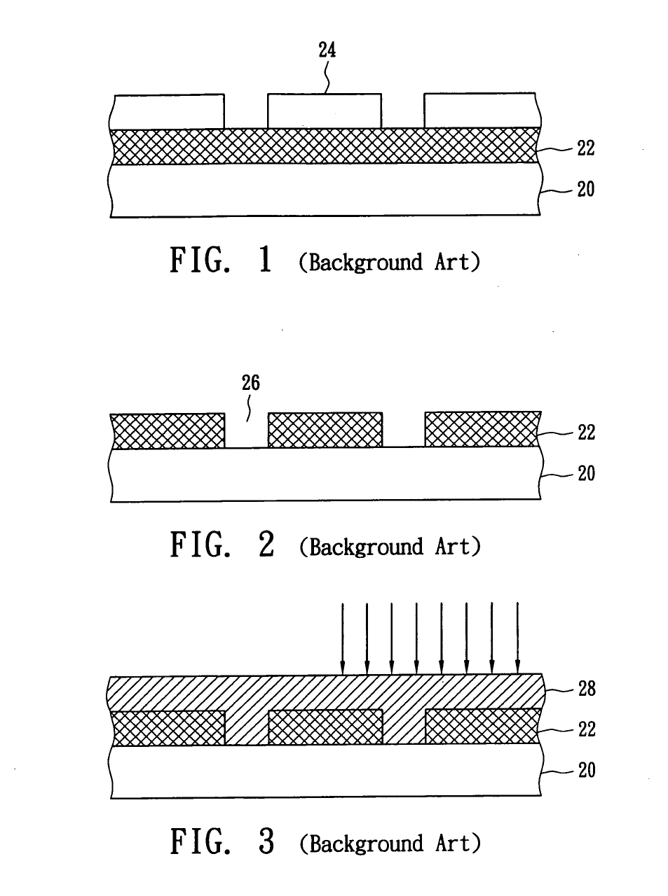

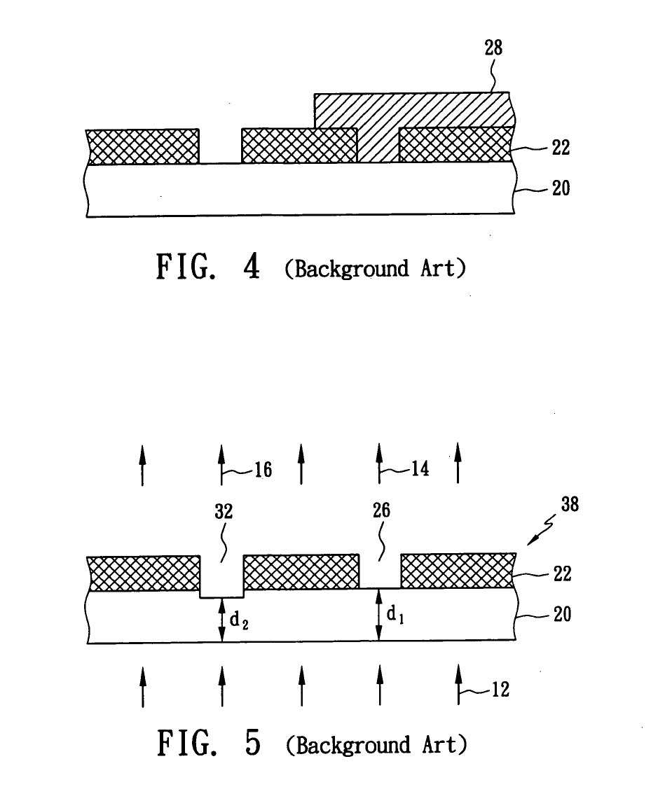

### DETAILED DESCRIPTION OF THE INVENTION

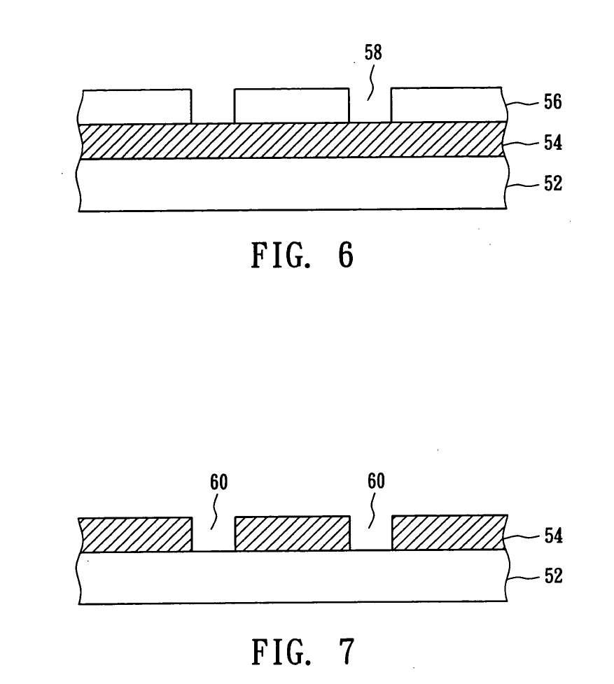

FIG. 6 to FIG. 9 illustrate a method for preparing a Levenson phase shifting mask 50 according to one embodiment of the present invention. The present method first deposits a chromium layer 54 on a quartz substrate 52, and a photoresist layer 56 including a plurality of opening patterns 58 is then formed on the chromium layer 54. An etching process is performed to remove a potion of the chromium layer 54 not covered by the photoresist layer, i.e., the portion of the chromium layer 54 under the opening pattern 58, down to the surface of the quartz substrate 52 to form a plurality of opening patterns 60 in the chromium layer 54, and then the photoresist layer 56 is completely removed by a stripping process, as shown in FIG. 7.

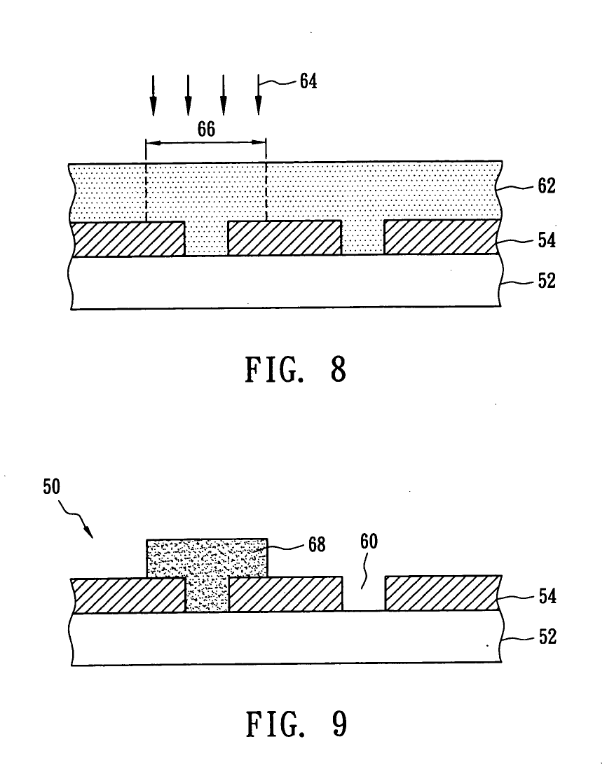

Referring to FIG. 8, a polymer layer 62 is formed on the quartz substrate 52 by a spin-coating process, and the polymer layer 62 covers the chromium layer 54 and fills the opening pattern 60. Energy is transported to the polymer layer 62 in a predetermined region 66, such as irradiating an electron beam 64 to the predetermined region 66, to change the chemical properties of the polymer layer 62 in the predetermined region, i.e., to change the molecular structure of the polymer layer 62 in the predetermined region 66. Subsequently, a developing process is performed to remove a portion of the polymer layer 62 not irradiated by the electron beam 64, i.e., the polymer layer 62 outside the predetermined region 66, while the polymer layer 62 in the predetermined region 66 remains to form a phase shifting pattern 68 on the opening pattern 60 of the chromium layer 54, as shown in FIG. 9.

The polymer layer 62 may include silsesquioxane. For example, the silsesquioxane can be hydrogen silsesqnioxane (HSQ), and a developing process using alkaline solution can be performed to remove the polymer layer 62 not irradiated by the electron beam 64, wherein the alkaline solution is selected from the group consisting of sodium hydroxide (NaOH) solution, potassium hydroxide (KOH) solution, and tetramethylamomnium hydroxide (TMAH) solution. In addition, the silsesquioxane can be methylsilsesquioxane (MSQ), and a developing process using an alcohol solution such as an ethanol solution is performed to remove the polymer layer 62 not irradiated by the electron beam 64. Further, the polymer layer 62 can include hybrid organic siloxane polymer (HOSP), and a developing process using a propyl acetate solution is performed to remove the polymer layer 62 not irradiated by the electron beam 64. The irradiation of the electron beam 64 will change the molecular structure of the polymer layer 62, for example, the molecular structure of hydrogen silsesqnioxane will transform into a network from a cage-like structure and polymer layer 62 will form a bonding with the quartz substrate 52. As a result, it is possible to selectively remove the polymer layer 62 outside the predetermined region 66 by a developing process using the alkaline solution.

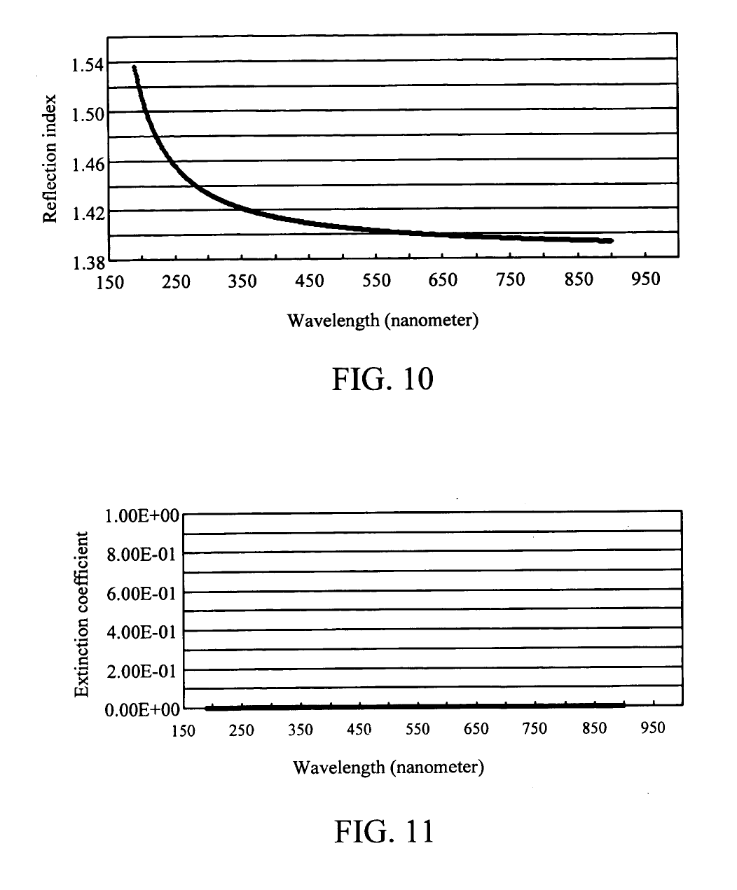

FIG. 10 is a diagram showing the variation of the reflection index of the polymer layer 62 under different wavelength after the irradiation of the electron beam 64 according to the present invention. According to known phase shifting formula: P=2π(n−1)d/mλ, where, P represents phase shifting angle, n represents the reflection index, and λ represents the wavelength of the exposure beam. When the wavelength of the exposure beam is set to be 193 nanometer, the corresponding reflection index is about 1.52, and the thickness of the phase shifting pattern 68 calculated according to the phase shifting formula should be 1828 Å. If the tolerance of the phase shifting angle is set to be 177° to 183°, the thickness of the phase shifting pattern 68 should be 1797 to 1858 nanometer. When the wavelength of the exposure beam is set to be 248 nanometer, the corresponding reflection index is about 1.45, and the thickness of the phase shifting pattern 68 calculated according to the phase shifting formula should be 2713 Å. If the tolerance of the phase shifting angle is set to be 177° to 183°, the thickness of the phase shifting pattern 68 should be 2668 to 2759 nanometer.

FIG. 11 is a diagram showing the variation of the extinction coefficient of the polymer layer 62 under different wavelength after the irradiation of the electron beam 64 according to the present invention. The extinction coefficient of the polymer layer 62 after the irradiation of the electron beam 64 is substantially zero as the wavelength of the exposure beam is between 190 and 900 nanometer. Therefore, the polymer layer 62 is a transparent after the irradiation of the electron beam 64, which can be applied to the lithographic mask.

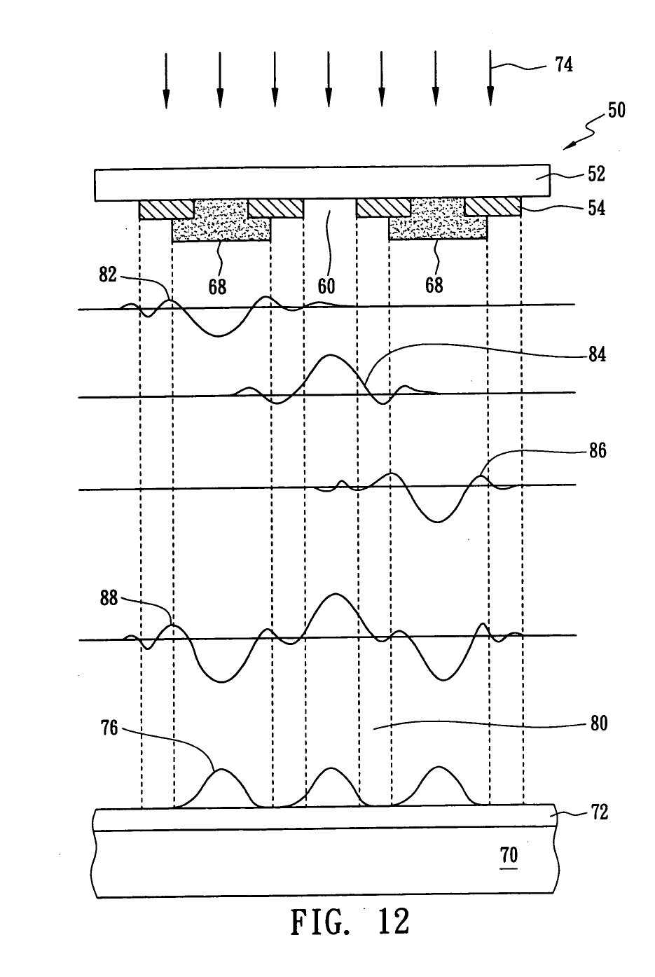

FIG. 12 is a schematic diagram showing the application of the phase shifting mask 50 to pattern a semiconductor device such as a gate of a transistor on a semiconductor substrate 71 according to one embodiment of the present invention. When an exposure beam 74 penetrates the phase shifting mask 50 to irradiate on a pre-coated photoresist layer 72 on the semiconductor substrate 70, the amplitude and the phase angle of the exposure beam 74 penetrating the phase shifting pattern 68 is shown by the curves 82 and 86, while the amplitude and the phase angle of the exposure beam 74 penetrating the opening pattern 60 is shown by the curve 84.

Particularly, the present invention uses an etching process to form the opening pattern 60 in the chromium layer 54, and the phase shifting pattern 68 is positioned on the opening pattern 60. Consequently, the thickness of the quartz substrate 52 under the opening pattern 60 and that under the phase shifting pattern 68 should be the same. In other words, when the exposure beam 74 penetrates the opening pattern 60 and the phase shifting pattern 68, it should penetrate the quartz substrate 52 with the same thickness theoretically, and the difference among the curves 82, 84 and 86 should be caused only by the phase shifting pattern 68. That is, the degree of the phase shifting angle of the phase shifting mask 50 primarily depends on the thickness of the phase shifting pattern 68, and is independent of the quartz substrate 52.

The curve 88 represents the amplitude of the curves 82, 84 and 86 after superposition, while the curve 76 represents the actual exposure intensity of the exposure beam 74 irradiating on the photoresist layer 72. A border region 80 is positioned between the phase shifting pattern 68 and the opening pattern 60, and the exposure intensity is substantially zero at the border region 80 of the photoresist layer 72. Since a zero exposure intensity cannot change the molecular structure of the photoresist layer 72, there are different chemical properties between the border region 80 and other region of the photoresist layer 72, and a developing process can selectively remove the border region 80 or other region of the photoresist layer 72 to improve the overall resolution of the lithographic process.

According to the present Levenson phase shifting mask, the thickness of the quartz substrate below the opening pattern is the same as that below the phase shifting pattern, and therefore the present invention can eliminate the phase error problem and the intensity imbalance problem originating from the two etching processes on the quartz substrate according to the prior art. In addition, the phase shifting pattern can be formed on the quartz substrate by the spin-coating process, which can precisely control the thickness of the phase shifting pattern and the phase shifting angle.

Further, the polymer layer includes silsesquioxane or hybrid organic siloxane polymer, whose molecular structure and chemical properties such as the solubility will be changed by the irradiation of the electron beam and the alkaline solution can be used to selectively remove a portion of the polymer layer. Since the electron beam possesses a very small diameter to irradiate on a very small region of the polymer layer, the present invention can precisely control the lateral width of the phase shifting pattern.

The above-described embodiments of the present invention are intended to be illustrative only. Numerous alternative embodiments may be devised by those skilled in the art without departing from the scope of the following claims.

What is claimed is:

1. A Levenson phase shifting mask, comprising:
a substrate;
a metal layer positioned on the substrate and including a plurality of openings; and
a phase shifting pattern positioned on the substrate and including a polymer material.

2. The Levenson phase shifting mask of claim 1, wherein the polymer material is silsesquioxane.

3. The Levenson phase shifting mask of claim 2, wherein the silsesquioxane is hydrogen silsesquioxane.

4. The Levenson phase shifting mask of claim 2, wherein the silsesquioxane is methylsilsesquioxane.

5. The Levenson phase shifting mask of claim 1, wherein the polymer material is hybrid organic siloxane polymer.

6. The Levenson phase shifting mask of claim 1, wherein the phase shifting pattern is positioned on one of the openings.

7. The Levenson phase shifting mask of claim 1, wherein the substrate is made of quartz.

8. The Levenson phase shifting mask of claim 1, wherein the metal layer is made of chrome.

9. A method for preparing a Levenson phase shifting mask, comprising steps of:
forming a metal layer on a substrate;
forming a plurality of openings in the metal layer;
forming a polymer layer on the substrate;
changing the molecular structure of the polymer layer in a predetermined region; and
removing a portion of the polymer layer outside the predetermined region.

10. The method for preparing a Levenson phase shifting mask of claim 9, wherein the step of forming a polymer layer on the substrate is performed by a spin-coating process.

11. The method for preparing a Levenson phase shifting mask of claim 9, wherein the polymer layer includes silsesquioxane.

12. The method for preparing a Levenson phase shifting mask of claim 11, wherein the silsesquioxane is hydrogen silsesquioxane.

13. The method for preparing a Levenson phase shifting mask of claim 12, wherein the step of removing a portion of the polymer layer outside the predetermined region is performed by using an alkaline solution.

14. The method for preparing a Levenson phase shifting mask of claim 13, wherein the alkaline solution is selected from the group consisting of sodium hydroxide, potassium hydroxide, and tetramethylamomnium hydroxide.

15. The method for preparing a Levenson phase shifting mask of claim 11, wherein the silsesquioxane is methylsilsesquioxane.

16. The method for preparing a Levenson phase shifting mask of claim 15, wherein the step of removing a portion of the polymer layer outside the predetermined region is performed by using an alcohol solution.

17. The method for preparing a Levenson phase shifting mask of claim 16, wherein the alcohol solution is an ethanol solution.

18. The method for preparing a Levenson phase shifting mask of claim 9, wherein the polymer layer includes hybrid organic siloxane polymer.

19. The method for preparing a Levenson phase shifting mask of claim 18, wherein the step of removing a portion of the polymer layer outside the predetermined region is performed by using a propyl acetate solution.

20. The method for preparing a Levenson phase shifting mask of claim 9, wherein the predetermined region is positioned on one of the openings.

21. The method for preparing a Levenson phase shifting mask of claim 9, wherein the step of changing the molecular structure of the polymer layer in a predetermined region is performed by using an electron beam to irradiate on the predetermined region.

22. The method for preparing a Levenson phase shifting mask of claim 9, wherein the step of changing the molecular structure of the polymer layer in a predetermined region is performed by providing energy to the predetermined region.

23. A method for preparing a semiconductor device, comprising steps of:
forming a photoresist layer on a substrate;
exposing the photoresist layer by using a Levenson phase shifting mask including a substrate, a metal pattern on the substrate, and a phase shifting pattern positioned on the substrate, wherein the phase shifting mask includes a polymer material; and
developing the photoresist layer.

24. The method for preparing a semiconductor device of claim 23, wherein the polymer material includes silsesquioxane.

25. The method for preparing a semiconductor device of claim 24, wherein the silsesquioxane is hydrogen silsesquioxane.

26. The method for preparing a semiconductor device of claim 24, wherein the silsesquioxane is methylsilsesquioxane.

27. The method for preparing a semiconductor device of claim 23, wherein the polymer material is hybrid organic siloxane polymer.

28. The method for preparing a semiconductor device of claim 23, wherein the phase shifting pattern is positioned on one of the openings.
